(19) United States
(12) Patent Application Publication
(10) Pub. No.: US 2025/0132245 A1
(43) Pub. Date: Apr. 24, 2025

(54) ELECTRICALLY SELF-INSULATED VIA

(71) Applicant: Intel Corporation, Santa Clara, CA (US)

(72) Inventors: Tofizur RAHMAN, Portland, OR (US); Conor P. Puls, Portland, OR (US); Payam Amin, Portland, OR (US); Santhosh Koduri, Portland, OR (US); Clay Mortensen, Portland, OR (US); Bozidar Marinkovic, Portland, OR (US); Shivani Falgun Patel, Hillsboro, OR (US); Richard Bonsu, Hillsboro, OR (US); Jaladhi Mehta, Beaverton, OR (US); Dincer Unluer, Hillsboro, OR (US)

(73) Assignee: Intel Corporation, Santa Clara, CA (US)

(21) Appl. No.: 18/491,111

(22) Filed: Oct. 20, 2023

(51) Int. Cl. H01L 23/522; H01L 23/528; H01L 23/532

(52) U.S. Cl. CPC H01L 23/5226; H01L 23/5283; H01L 23/5329

(57) ABSTRACT

A fabrication method and associated integrated circuit (IC) structures and devices that include one or more self-insulated vias is described herein. In one example, an IC structure includes a via surrounded by an insulator material and a layer of insulator material between a conductive material of the via and the surrounding insulator material. In one example, the layer of insulator material has one or more material properties that are different than the surrounding insulator material, including one or more of a different density, a different dielectric constant, and a different material composition.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component (e.g., the conductive interconnects for signaling, power delivery, and ground) is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a perspective view of an example nanoribbon field-effect transistor (FET), according to one embodiment of the present disclosure.

FIG. 2 is a top-down view of an IC device including an electrically self-insulated via, according to one embodiment of the present disclosure.

FIGS. 3A-3C are cross-sectional side views along different cross-sections of the IC device of FIG. 2, according to some embodiments of the present disclosure.

FIGS. 4A-4F are cross-sectional side views illustrating provision of backside interconnects for the IC device of FIG. 2, according to some embodiments of the present disclosure.

FIG. 5 is a flow diagram of an example method for fabricating an IC structure that includes a self-insulated via, in accordance with some embodiments.

FIGS. 6A-6D provide cross-sectional side views at various stages in the fabrication of an example IC structure according to the method of FIG. 5, in accordance with some embodiments.

FIG. 7 illustrates another example of an IC structure with a self-insulated via, in accordance with embodiments.

FIG. 8 is a top view of a wafer and dies that may include any of the IC devices disclosed herein, in accordance with any of the embodiments disclosed herein.

FIG. 9 is a side, cross-sectional view of an IC package that may include any of the IC devices disclosed herein, in accordance with various embodiments.

FIG. 10 is a side, cross-sectional view of an IC device assembly that may include any of the IC devices disclosed herein, in accordance with any of the embodiments disclosed herein.

FIG. 11 is a block diagram of an example electrical device that may include any of the IC devices disclosed herein, in accordance with any of the embodiments disclosed herein.

### DETAILED DESCRIPTION

Disclosed herein are IC structures and devices including electrically self-insulated vias. In some embodiments, vias (e.g., deep trench vias) may be used for backside power/signal/ground delivery. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

As IC structures become more compact with smaller feature sizes and higher device density, new challenges arise in the fabrication processes of such devices. For example, in some IC structures, conductive vias are placed between conductive peripherals (such as conductive gates of transistors). Defects in the conductive peripherals can lead to shorting (i.e., to creating an unintentional electrical connection) between a via and conductive peripherals, which can result in device failure. Voids in the insulator material between a via and adjacent devices, which may be intrinsic or introduced during subsequent processing, can also lead to unintentional electrical connection between the via and adjacent devices.

In accordance with embodiments described herein, an electrically self-insulated via includes one or more layers of insulator material (e.g., an insulative liner) between a conductive fill material of the via and a surrounding insulator material. In one example, the liner, which may be provided after via etch and prior to via metallization, can provide protection against non-uniformities or defects to prevent shorting and device failure. The terms liner, insulative liner, and insulator layer are used in some of the following examples when referring to one or more layers of insulator material between a conductive material of the via and a surrounding insulator material. A liner including an insulator material could also be referred to as a spacer, spacer layer, insulative spacer, or insulative barrier layer. The terms self-insulated via and electrically self-insulated via are used herein to refer to a via that has one or more layers of insulator material between the conductive material in the via and the insulator material surrounding the via. A self-insulated via could also be referred to as a self-spaced via. The terms via, deep trench via, interconnect, and conductive interconnect may also be used in reference to a self-insulated conductive via in accordance with examples herein.

While some descriptions are provided herein with respect to the use of deep trench vias for backside power delivery, embodiments of the present disclosure are equally applicable to using vias for backside signal or ground delivery, as well as to vias being used for purposes of delivering power, signal, or ground to IC components from the front side.

IC structures as described herein, in particular IC structures including self-insulated vias, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of a radio frequency (RF) receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

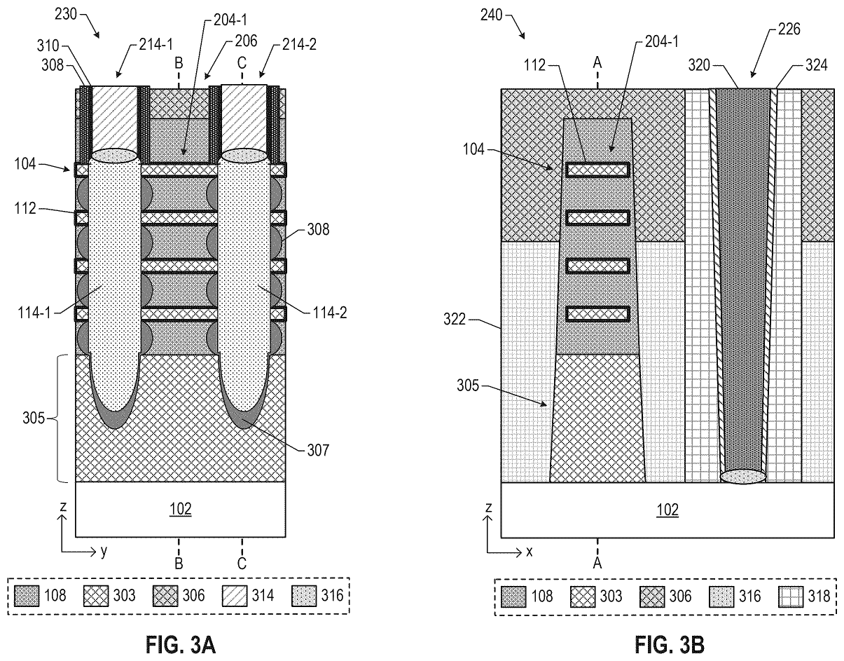

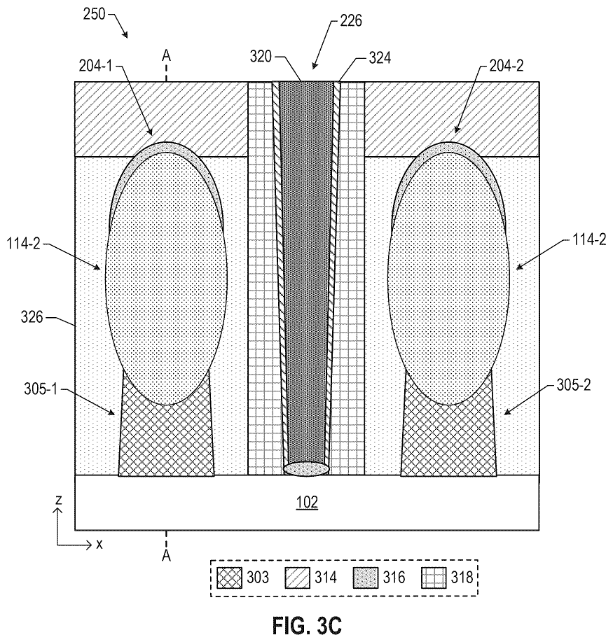

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 3A-3C, such a collection may be referred to herein without the letters, e.g., as “FIG. 3.”

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of the presence of IC structures that include self-insulated vias as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

IC structures including self-insulated vias may also include transistors of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surfaces. A confinement surface refers to a particular orientation of the channel surface that is confined by the gate field. Non-planar transistors potentially improve performance relative to transistors having a planar architecture, such as single-gate transistors.

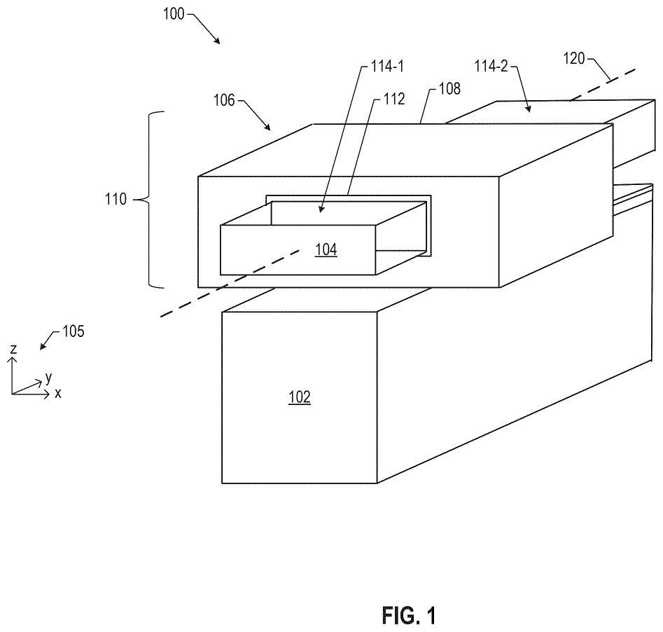

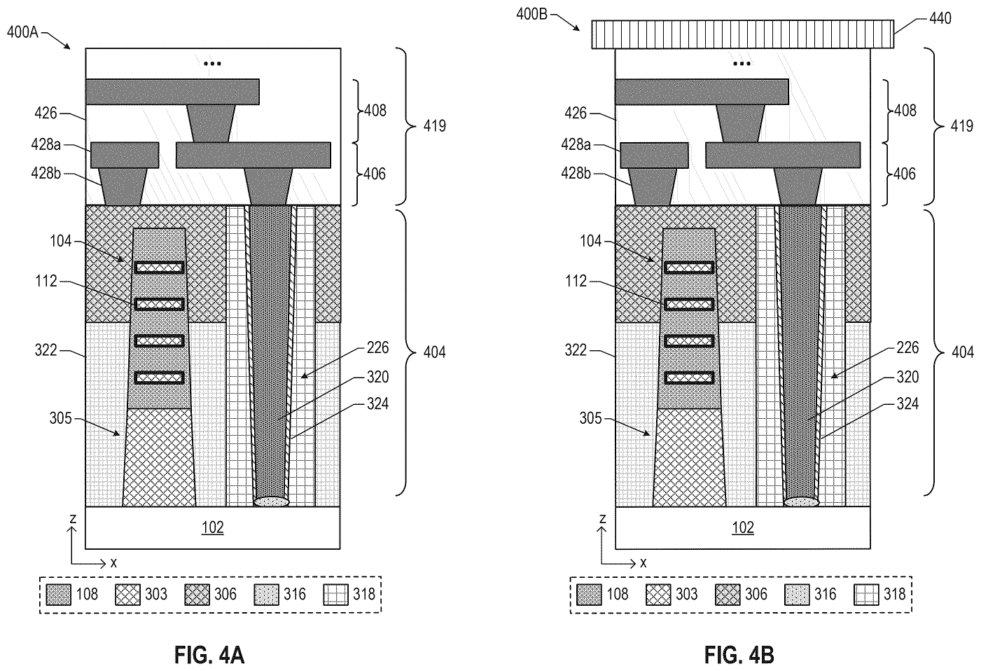

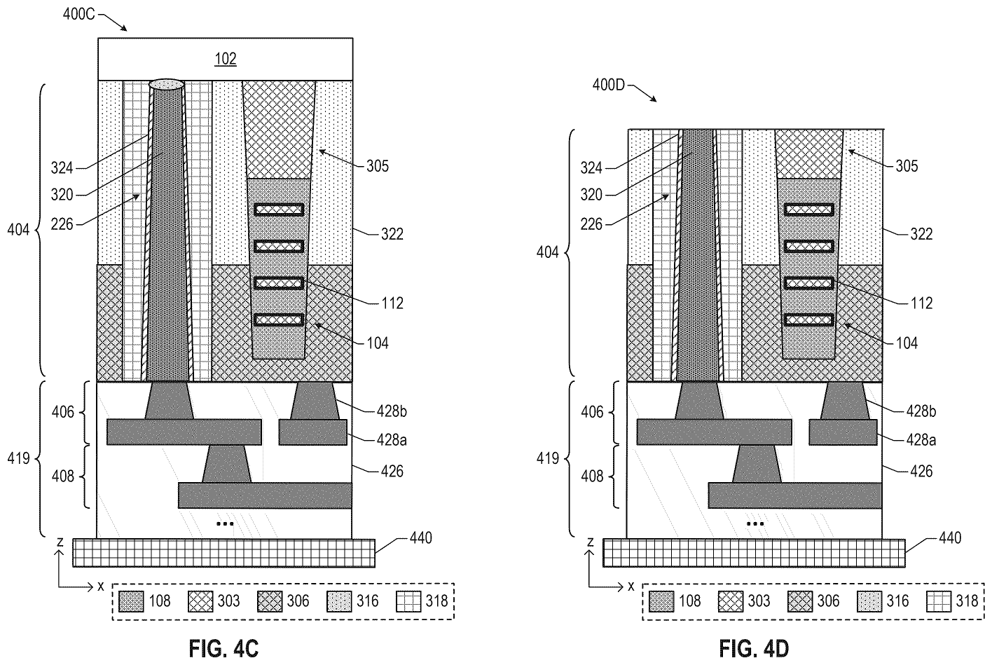

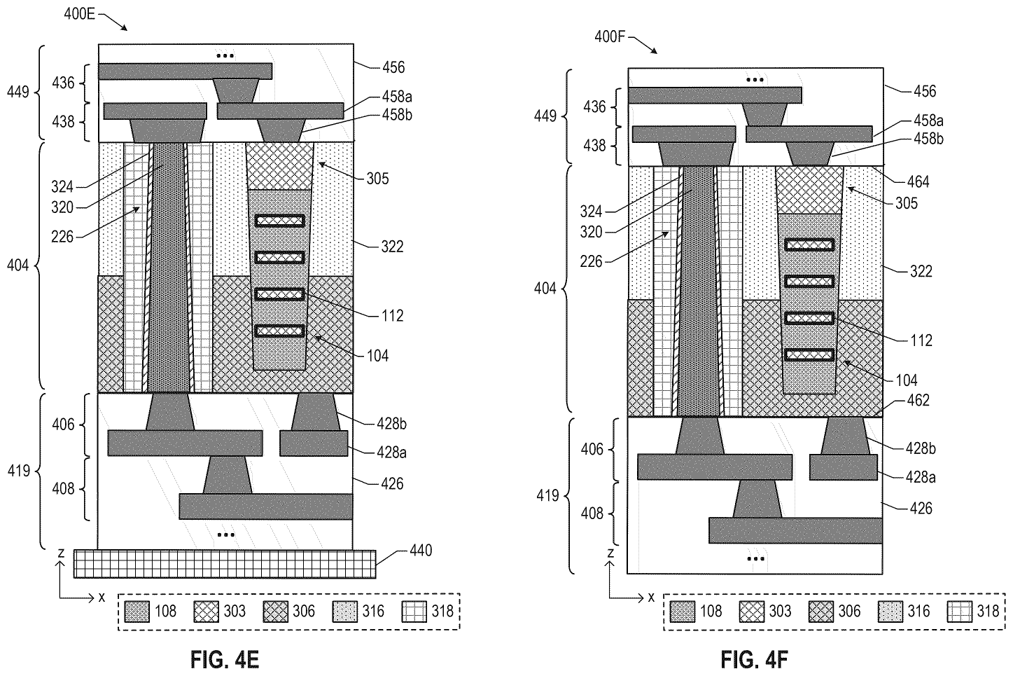

Nanoribbon transistors may be particularly advantageous for continued scaling of complementary metal-oxide-semiconductor (CMOS) technology nodes due to the potential to form gates on all four sides of a channel material (hence, such transistors are sometimes referred to as “gate all around” transistors). Therefore, some IC structures illustrated herein show nanoribbon transistors as an example (e.g., IC structures shown in FIG. 1, FIG. 3, and FIG. 4), although IC structures that include self-insulated vias as described herein may include other devices instead of or in addition to nanoribbon transistors, and are not limited to such transistors.

As used herein, the term “nanoribbon” refers to an elongated structure of a semiconductor material having a longitudinal axis parallel to a support structure (e.g., a substrate, a die, a chip, or a wafer) over which such a structure is built. Typically, a length of a such a structure (i.e., a dimension measured along the longitudinal axis, shown in the present drawings to be along the y-axis of an example x-y-z coordinate system 105 shown in FIG. 1) is greater than each of a width (i.e., a dimension measured along the x-axis of the coordinate system 105) and a thickness/height (i.e., a dimension measured along the z-axis of the coordinate system 105). In some settings, the terms “nanoribbon” or “nanosheet” have been used to describe elongated semiconductor structures that have a rectangular transverse cross-section (i.e., a cross-section in a plane perpendicular to the longitudinal axis of the structure), while the term “nanowire” has been used to describe similar elongated structures but with circular transverse cross-sections. In the present disclosure, the term “nanoribbon” is used to refer to all such nanowires, nanoribbons, and nanosheets, as well as elongated semiconductor structures with a longitudinal axis parallel to the support structures and with having transverse cross-sections of any geometry (e.g., transverse cross-sections in the shape of an oval or a polygon with rounded corners). A transistor may then be described as a “nanoribbon transistor” if the channel of the transistor is a portion of a nanoribbon, i.e., a portion around which a gate stack of a transistor may wrap around. The semiconductor material in the portion of the nanoribbon that forms a channel of a transistor may be referred to as a “channel material,” with source and drain regions of a transistor provided on either side of the channel material.

FIG. 1 provides a perspective view of an example IC structure 100 with a nanoribbon transistor 110, according to some embodiments of the present disclosure. As shown in FIG. 1, the IC structure 100 includes a semiconductor material formed as a nanoribbon 104 extending substantially parallel to a support 102. The transistor 110 may be formed on the basis of the nanoribbon 104 by having a gate stack 106 wrap around at least a portion of the nanoribbon referred to as a “channel portion” and by having source and drain regions, shown in FIG. 1 as a first S/D region 114-1 and a second S/D region 114-2, on either side of the gate stack 106. One of the S/D regions 114 is a source region and the other one is a drain region. However, because, as is common in the field of FETs, designations of source and drain are often interchangeable, they are simply referred to herein as a first S/D region 114-1 and a second S/D region 114-2.

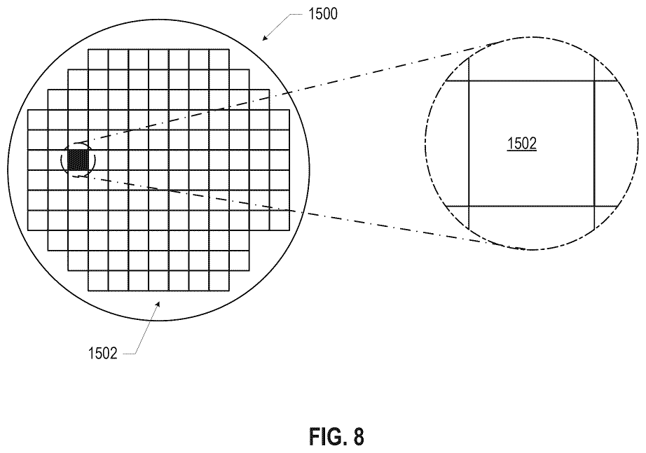

Implementations of the present disclosure may be formed or carried out on any suitable support 102, such as a substrate, a die, a wafer, or a chip. The support 102 may, e.g., be the wafer 1500 of FIG. 8, discussed below, and may be, or be included in, a die, e.g., the singulated die 1502 of FIG. 8, discussed below. The support 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 102 may be a printed circuit board (PCB) substrate, a package substrate, an interposer, a wafer, or a die. Although a few examples of materials from which the support 102 may be formed are described here, any material that may serve as a foundation upon which an IC structure including a self-insulated via as described herein may be built falls within the spirit and scope of the present disclosure. Although only one nanoribbon 104 is shown in FIG. 1, the IC structure 100 may include a stack of such nanoribbons where a plurality of nanoribbons 104 are stacked above one another. For example, FIG. 3 and FIG. 4 show IC structures that may be examples of the IC structure 100. In some embodiments, a portion of the support 102 right below the lowest nanoribbon 104 of the stack may be shaped as a subfin extending away from a base, as is known in the field of nanoribbon transistors.

The nanoribbon 104 may take the form of a nanowire or nanoribbon, for example. In some embodiments, an area of a transversal cross-section of the nanoribbon 104 (i.e., an area in the x-z plane of an x-y-z coordinate system 105 shown in FIG. 1, perpendicular to a longitudinal axis 120 of the nanoribbon 104) may be between about 25 and 10000 square nanometers, including all values and ranges therein (e.g., between about 25 and 1000 square nanometers, or between about 25 and 500 square nanometers). In some embodiments, a width of the nanoribbon 104 (i.e., a dimension measured in a plane parallel to the support 102 and in a direction perpendicular to the longitudinal axis 120 of the nanoribbon 104, e.g., along the x-axis of the coordinate system 105) may be at least about 3 times larger than a height of the nanoribbon 104 (i.e., a dimension measured in a plane perpendicular to the support 102, e.g., along the z-axis of the coordinate system 105), including all values and ranges therein, e.g., at least about 4 times larger, or at least about 5 times larger. Although the nanoribbon 104 illustrated in FIG. 1 is shown as having a rectangular cross-section, the nanoribbon 104 may instead have a cross-section that is rounded at corners or otherwise irregularly shaped, and the gate stack 106 may conform to the shape of the nanoribbon 104. The term “face” of a nanoribbon may refer to the side of the nanoribbon 104 that is larger than the side perpendicular to it (when measured in a plane substantially perpendicular to the longitudinal axis 120 of the nanoribbon 104), the latter side being referred to as a “sidewall” of a nanoribbon.

In various embodiments, the semiconductor material of the nanoribbon 104 may be composed of semiconductor material systems including, for example, N-type or P-type materials systems. In some embodiments, the nanoribbon 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 104 may include a combination of semiconductor materials. In some embodiments, the nanoribbon 104 may include a monocrystalline semiconductor, such as silicon (Si) or germanium (Ge). In some embodiments, the nanoribbon 104 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistor 110 is an N-type metal-oxide-semiconductor (NMOS) transistor), the channel material of the nanoribbon 104 may include a III-V material having a relatively high electron mobility, such as, but not limited to InGaAs, InP, InSb, and InAs. For some such embodiments, the channel material of the nanoribbon 104 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a P-type metal-oxide-semiconductor (PMOS) transistor), the channel material of the nanoribbon 104 may advantageously be a group IV material having a high hole mobility, such as, but not limited to Ge or a Ge-rich SiGe alloy. For some example embodiments, the channel material of the nanoribbon 104 may have a Ge content between 0.6 and 0.9, and advantageously may be at least 0.7.

In some embodiments, the channel material of the nanoribbon 104 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 104 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 104 may have a thickness between about 5 and 75 nanometers, including all values and ranges therein. In some embodiments, a thin-film channel material may be deposited at relatively low temperatures, which allows depositing the channel material within the thermal budgets imposed on back-end fabrication to avoid damaging other components, e.g., front-end components such as the logic devices.

A gate stack 106 including a gate electrode material 108 and, optionally, a gate insulator material 112, may wrap entirely or almost entirely around a portion of the nanoribbon 104 as shown in FIG. 1, with the active region (channel region) of the channel material of the transistor 110 corresponding to the portion of the nanoribbon 104 wrapped by the gate stack 106. As shown in FIG. 1, the gate insulator material 112 may wrap around a transversal portion of the nanoribbon 104 and the gate electrode material 108 may wrap around the gate insulator material 112.

The gate electrode material 108 may include one or more gate electrode materials, where the choice of the gate electrode materials may depend on whether the transistor 110 is a PMOS transistor or an NMOS transistor. For a PMOS transistor, gate electrode materials that may be used in different portions of the gate electrode material 108 may include, but are not limited to, ruthenium, palladium, platinum, cobalt, nickel, and conductive metal oxides (e.g., ruthenium oxide). For an NMOS transistor, gate electrode materials that may be used in different portions of the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of a plurality of gate electrode materials, where zero or more materials of the stack are workfunction (WF) materials and at least one material of the stack is a fill metal layer. Further materials/layers may be included next to the gate electrode material 108 for other purposes, such as to act as a diffusion barrier layer or/and an adhesion layer.

In some embodiments, the gate insulator material 112 may include one or more high-k dielectrics including any of the materials discussed herein with reference to the insulator material that may surround portions of the transistor 110. In some embodiments, an annealing process may be carried out on the gate insulator material 112 during fabrication of the transistor 110 to improve the quality of the gate insulator material 112. The gate insulator material 112 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 106 may be surrounded by a gate spacer, not shown in FIG. 1. Such a gate spacer would be configured to provide separation between the gate stack 106 and S/D contacts of the transistor 110 and could be made of a low-k dielectric material, some examples of which have been provided above.

Turning to the S/D regions 114 of the transistor 110, in some embodiments, the S/D regions may be highly doped, e.g., with dopant concentrations of about 10²¹ cm⁻³, in order to advantageously form Ohmic contacts with the respective S/D contacts (not shown in FIG. 1), although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a channel material extending between the first S/D region 114-1 and the second S/D region 114-2), and, therefore, may be referred to as “highly doped” (HD) regions. Even when doped to realize threshold voltage tuning as described herein, the channel portions of transistors typically include semiconductor materials with doping concentrations significantly smaller than those of the S/D regions 114.

The S/D regions 114 of the transistor 110 may generally be formed using either an implantation/diffusion process or an etching/deposition process. In the former process, dopants such as boron, aluminum, antimony, phosphorous, or arsenic may be ion-implanted into the nanoribbon 104 to form the source and drain regions. An annealing process that activates the dopants and causes them to diffuse further into the nanoribbon 104 may follow the ion implantation process. In the latter process, portions of the nanoribbon 104 may first be etched to form recesses at the locations of the future S/D regions 114. An epitaxial deposition process may then be carried out to fill the recesses with material that is used to fabricate the S/D regions 114. In some implementations, the S/D regions 114 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114 may be formed using one or more alternate semiconductor materials such as germanium or a group III-V material or alloy. And in further embodiments, one or more layers of metal and/or metal alloys may be used to form the S/D regions 114. In some embodiments, a distance between the first and second S/D regions 114 (i.e., a dimension measured along the longitudinal axis 120 of the nanoribbon 104) may be between about 5 and 40 nanometers, including all values and ranges therein (e.g., between about 22 and 35 nanometers, or between about 20 and 30 nanometers).

The IC structure 100 shown in FIG. 1, as well as IC structures shown in other drawings of the present disclosure, is intended to show relative arrangements of some of the components therein, and the IC structure 100, or portions thereof, may include other components that are not illustrated (e.g., electrical contacts to the S/D regions 114 of the transistor 110, additional layers such as a spacer layer around the gate electrode of the transistor 110, etc.). For example, although not specifically illustrated in FIG. 1, a dielectric spacer may be provided between a first S/D contact (which may also be referred to as a “first S/D electrode”) coupled to a first S/D region 114-1 of the transistor 110 and the gate stack 106 as well as between a second S/D contact (which may also be referred to as a “second S/D electrode”) coupled to a second S/D region 114-2 of the transistor 110 and the gate stack 106 in order to provide electrical isolation between the source, gate, and drain electrodes. In another example, although not specifically illustrated in FIG. 1, at least portions of the transistor 110 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 110 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

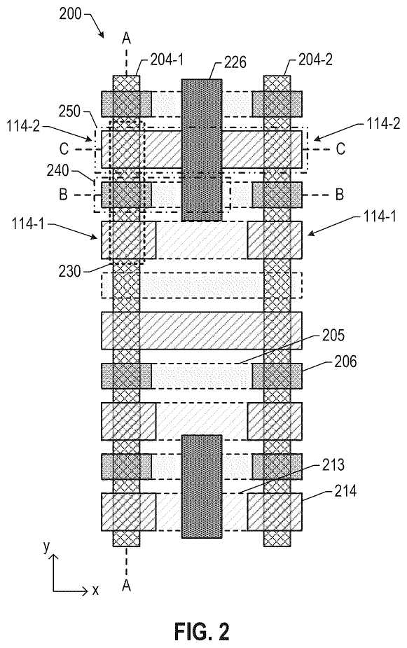

FIG. 2 is a top-down view of an IC structure 200 that may include self-insulated vias, according to one embodiment of the present disclosure. Some of the materials are not shown in the top-down view in order to not obscure the drawing.

As shown in FIG. 2, the IC structure 200 may include two nanoribbon stacks 204-1 and 204-2 (collectively referred to as “nanoribbon stacks 204”), if the transistors to be implemented in the IC structure 200 are nanoribbon transistors such as the one illustrated in FIG. 1. Alternatively, what is now shown as nanoribbon stacks 204-1 and 204-2 could be fins, if the transistors to be implemented in the IC structure 200 are FinFETs. The nanoribbon stacks 204 may include stacks of one or more nanoribbons 104 as described above and may be provided over a support such as the support 102 (not specifically shown in FIG. 2). The nanoribbon stacks 204 may extend substantially parallel to one another, e.g., along the y-axis of the coordinate system 105, consistent with the illustration of FIG. 1. Metal gate lines 205 (shown in FIG. 2 to be within dashed contours) and S/D contact lines 213 may extend substantially perpendicular to the nanoribbon stacks 204 and substantially parallel to one another, e.g., along the x-axis of the coordinate system 105. FIG. 2 illustrates that the metal gate lines 205 and the S/D contact lines 213 may be provided in an alternating manner. Metal gate lines 205 may be cut and removed where the deep trench vias are placed, so that gate contacts 206 effectively act as portions of the metal lines 205. In FIG. 2, portions of the metal gate lines 205 are shown with dashed contours, indicating that these are the portions where the metal gate lines 205 have been removed. The gate contacts 206 are in conductive contact with the gate stacks 106 (which are underneath the gate contacts 206 and, therefore, not seen in the view of FIG. 2) provided over channel portions of the nanoribbon stacks 204, providing electrical connectivity to the gates of the nanoribbon transistors. Thus, portions of the gate contacts 206 intersecting the gate stacks 106 are in conductive contact with the gate stacks 106 and serve as gate contacts for the transistors.

Similarly, S/D contact lines 213 may be cut and removed where the deep trench vias are placed, so that S/D contacts 214 effectively act as portions of the S/D contact lines 213. In FIG. 2, portions of the S/D contact lines 213 are shown with dashed contours, indicating that these are the portion where the S/D contact lines 213 have been removed. The S/D contacts 214 are provided over S/D regions 114 (which are underneath the S/D contacts 214 and, therefore, not seen in the view of FIG. 2) of the nanoribbon stacks 204, providing electrical connectivity to the S/D regions 114 of the nanoribbon transistors. Thus, portions of the S/D contacts 214 intersecting the S/D regions 114 are in conductive contact with the S/D regions 114 and serve as S/D contacts for the transistors.

FIG. 2 further illustrates that deep trench vias 226 may be provided in the vicinity of the transistors formed on the basis of the nanoribbon stacks 204. Two instances of the deep trench vias 226 are shown in FIG. 2, but, in other embodiments, any other number of one or more deep trench vias 226 may be included in the IC structure 200. Similarly, while a particular arrangement of gate stacks 106, metal gate lines 205, gate contacts 206, S/D contact lines 213, and S/D contacts 214 is shown in FIG. 1 and FIG. 2, in other embodiments, these elements may be arranged differently within the IC structure 200.

In order to further illustrate details of the IC structure 200, FIG. 2 shows a portion 230 (illustrated with a dotted contour), a portion 240 (illustrated with a dot-dashed contour), and a portion 250 (illustrated with a double-dot-dashed contour). The portion 230 indicates an approximate outline of an example transistor such as the transistor 110, provided over the nanoribbon stack 204-1. The portion 240 illustrates a portion of the IC structure 200 with a gate contact 206 provided over a gate stack 106 over a channel portion of the nanoribbon stack 204-1 and a deep trench via 226. FIGS. 3A-3C are cross-sectional side views along different cross-sections of the IC structure 200 of FIG. 2, according to some embodiments of the present disclosure. In particular, FIG. 3A illustrates a cross-sectional side view of the portion 230 along a plane AA shown in FIG. 2, FIG. 3B illustrates a cross-sectional side view of the portion 240 along a plane BB shown in FIG. 2, and FIG. 3C illustrates a cross-sectional side view of the portion 250 along a plane CC shown in FIG. 2. A number of elements referred to in the description of FIGS. 3A-3C, as well as in FIGS. 4A-4F, with reference numerals are illustrated in these drawings with different patterns, with a legend showing the correspondence between the reference numerals and patterns being provided at the bottom of each drawing page containing FIGS. 3A-3C and FIGS. 4A-4F. For example, the legend illustrates that FIGS. 3A-3C use different patterns to show a gate electrode material 108, a semiconductor material 303, an electrically conductive material 306 of a gate contact 206, and so on.

As shown in FIG. 3A, the portion 230 includes a transistor similar to the transistor 110 but built on the basis of a nanoribbon stack 204-1 of a plurality of nanoribbons 104 instead of just one nanoribbon 104 as shown in FIG. 1. While four nanoribbons 104 are shown to be included in the nanoribbon stack 204-1, in other embodiments, fewer nanoribbons 104 or more nanoribbons 104 may be included. FIG. 3A illustrates a semiconductor material 303 as the material of the nanoribbons 104, further illustrating a subfin 305 of the semiconductor material 303 below the nanoribbon stack 204-1, although in some embodiments the nanoribbons 104 and at least a portion of the subfin 305 may include semiconductor materials of different material compositions. As shown in FIG. 3A, a gate stack having a gate insulator material 112 and a gate electrode material 108 may wrap around channel portions of the nanoribbons 104. FIG. 3A further illustrates a first S/D region 114-1 and a second S/D region 114-2 extending through the nanoribbon stack 204-1, electrically insulated/separated from the gate electrode material 108 and from the semiconductor material 303 of the subfin 305 by an insulator material 307. In some embodiments, the insulator material 307 may form so-called “dimples” 308 in areas where the insulator material 307 separates the S/D regions 114 from the gate electrode material 108. The insulator material 307 may include any of the insulator materials described herein, e.g., any of the ILD materials described above.

Above the nanoribbon stack 204-1, FIG. 3A illustrates a gate contact 206 and S/D contacts 214 on either side of the gate contact 206, individually labeled as a first S/D contact 214-1 for making electrical contact to the first S/D region 114-1 and a second S/D contact 214-2 for making electrical contact to the second S/D region 114-2. The gate contact 206 may include an electrically conductive material 306 in electrically conductive contact with the gate electrode material 108. In various embodiments, material compositions of the electrically conductive material 306 and the gate electrode material 108 may be substantially the same or different.

The S/D contacts 214 may be electrically isolated from the gate electrode material 108 and the electrically conductive material 306 of the gate contact 206 by gate spacers 308. The gate spacers 308 may include one or more of spacer materials, diffusion barrier materials, adhesion materials, etc., as known in the art for forming contacts to various components of IC structures. In some embodiments, the gate spacers 308 may include low-k dielectrics and/or any of the ILD materials described above. Optionally, sidewalls of the S/D contacts 214 may be lined with one or more liners 310, where the liners 310 may include, but not limited to, materials comprising silicon and nitrogen (e.g., silicon nitride), materials comprising silicon and oxygen (e.g., silicon oxide), materials comprising silicon and carbon (e.g., silicon carbide), and/or their composites. Within the sidewalls, the S/D contacts 214 may be filled with an electrically conductive fill material 314. In various embodiments, material compositions of the electrically conductive fill material 314 and the electrically conductive material 306 may be substantially the same (e.g., both may include/be tungsten) or different. At the bottom of the S/D contacts 214, an interface material 316 is deposited to provide an interface between the S/D regions 114 and the electrically conductive fill material 314 of S/D contacts 214. The interface material 316 may include/be a metal such as titanium which, once deposited, may intermix with the material of the S/D regions 114, e.g., with silicon, forming a compound (e.g., titanium silicide) that may help reduce contact resistance of the S/D contacts 214. Although FIG. 3A illustrates an example in which the interface material 316 is only present on the bottom of the S/D contacts 214 and not the sidewalls of the S/D contacts 214, in other examples the interface material 316 may be present on the bottom and sidewalls of the S/D contacts 214. In other embodiments, the interface material 316 is optional and may be absent from the bottom and/or absent from the side walls of the S/D contacts 214.

FIG. 3B shows a cross-sectional side view of the IC structure 200 along the plane BB shown in FIG. 2 and in FIG. 3A (i.e., a gate cut). FIG. 3C shows the plane AA along which the cut of FIG. 3A is shown. Turning to FIG. 3B, the portion 240 illustrates a deep trench via 226, an insulator material 318 surrounding the deep trench via 226, an electrically conductive via fill material 320 filling the deep trench via 226, and an insulator material 322 surrounding sidewalls of the subfin 305. The insulator material 318 and the insulator material 322 may, e.g., include any of the ILD materials described above and may have either substantially the same or different material compositions. The insulator material 322 may sometimes be referred to as a “shallow-trench insulator” (STI). The insulator material 322 is provided to electrically isolate the deep trench via 226 from the adjacent electrically conductive structures and materials, e.g., to electrically isolate the deep trench via 226 from the electrically conductive material 306 of the gate contact 206, which may extend along any of the metal gate lines 205. The electrically conductive via fill material 320 filling the deep trench via 226 may include any suitable conductive material, e.g., tungsten, and may have substantially the same or different material composition with the electrically conductive material 306 of the gate contact 206 and/or with the electrically conductive fill material 314 of the S/D contacts 214.

In some embodiments, sidewalls of the deep trench via 226 may be lined with a liner 324 that includes one or more insulator materials. In one example, the liner 324 is or includes an insulator layer between the conductive via fill material 320 and the insulator material 318. The liner 324 may be in contact with the insulator layer 318 and or/in contact with the conductive via fill material 320, or there may be intervening layers, such as a conductive or semiconductive layer between the liner 324 and the conductive via fill material 320. The liner 324 may include, but is not limited to, one or more of the ILD materials described above. In some examples, the liner 324 may include silicon oxide, silicon carbide, silicon nitride, a composite including any combination of silicon and one or more of oxygen, nitrogen, and/or carbon (e.g., a composite of silicon, oxygen, and nitrogen, a composite of silicon oxygen, and carbon, a composite of silicon, nitrogen, and carbon, or a composite of silicon, nitrogen, oxygen, and carbon), or any other suitable insulator material.

The liner 324 and the insulator material 318 can have the same material properties or different material properties. For example, the liner 324 may include the same or a different material composition than the surrounding insulator material 318. The liner 324 may have the same or a different density than the insulator material 318. In one example, whether the liner 324 has the same or a different material composition than the insulator material 318, the liner 324 includes an insulator material that has a higher density than the insulator material 318. For example, the liner 324 may be deposited using a different process than the insulator material 318, resulting in a higher density insulator layer that has fewer voids than the insulator material 318. In another example, the density of the liner 324 can be substantially the same as the density of the surrounding insulator material 318. In one example, the liner 324 (or at least one layer of the liner 324 in the case of a multi-layered liner) has at least one material property (e.g., material composition, density, dielectric constant, etc.) that is different than the corresponding material property of the insulator material 318.

In one example, the thickness of the liner 324 is sufficiently thick to prevent electrical shorting between the conductive via fill material 320 and adjacent devices, but not so thick as to prevent the via opening from being filled with a sufficient volume of conductive via fill material 320. In one example, a thickness of the liner 324 is less than about 50% of a width of the conductive via fill material 320, where a thickness of the liner 324 and the width of the via fill material 320 are dimensions measured in a plane substantially parallel to the support 102 (i.e., parallel to the x-y plane of an x-z coordinate system shown in FIG. 3B, wherein the y-axis is going into and coming out of the page of FIG. 3B). In one such example, a thickness of the liner 324 is less than about 50% of a width of the conductive via fill material 320 at the narrowest point of the conductive via fill material 320. In one example, a thickness of the liner 324 is greater than about 3 nanometers. In one example, the thickness of the liner is less than the width of the insulator material 318 surrounding the conductive via (e.g., the volume of the insulator material 318 surrounding the conductive via fill material 320 is greater than the volume of the liner 324). Other liner thicknesses are possible, and it is to be understood that the thickness of the liner 324 may vary at different points along the length of the conductive via.

Thus, a liner 324 including an insulator material on sidewalls of the deep trench via 226 can prevent the conductive via fill material 320 from unintentionally conducting to adjacent devices (e.g., prevent unintentional electrical connection with adjacent transistor gates and contacts). As the density of features in an IC structure increase, the risk of such unintentional conductivity to adjacent devices increases, which can result in device failures. Including a liner 324 with an insulator material can prevent electrical shorts from the via to the adjacent devices.

FIG. 3C provides another helpful illustration of the IC structure 200 along the plane CC shown in FIG. 2 and in FIG. 3A (i.e., a cut across S/D regions 114 of two different nanoribbon stacks 204). FIG. 3C shows the plane AA along which the cut of FIG. 3A is shown.

FIG. 3C illustrates the deep trench via 226, an insulator material 318 surrounding the deep trench via 226 as shown in FIG. 3B, a liner including an insulator material between the insulator material 318 and the conductive via fill material 320, and two S/D regions 114-2, one on each side of the deep trench via 226 and electrically insulated from the deep trench via 226 by the insulator material 318. The two S/D regions 114-2 are provided over different ones of the nanoribbon stacks 204-1 and 204-2, as shown in FIG. 2 and FIG. 3C. FIG. 3C further illustrates an insulator material 326 that may surround the S/D regions 114 below the electrically conductive fill material 314 of the S/D contacts 214, and may also surround the sidewalls of the subfins 305 of the nanoribbon stacks 204-1 and 204-2. The insulator material 326 may, e.g., include any of the ILD materials described above and may have either substantially the same or different material compositions with any other insulator materials in the IC structure 200, e.g., with the insulator material 322 shown in FIG. 3B. As mentioned above, the liner 324 may have the same or a different material composition than the insulator material 318.

FIG. 3C shows the interface material 316 onto the S/D regions 114-2 and at the bottom of the deep trench via 226, however, as mentioned above, an interface may be present or absent at one or more of: the bottom and/or sidewalls of the deep trench via 226 and the bottom and/or sidewalls of openings for the S/D contacts 214.

FIGS. 4A-4F are cross-sectional side views illustrating provision of backside interconnects for the IC structure 200 of FIG. 2, according to some embodiments of the present disclosure. Each of FIGS. 4A-4F illustrates the same cross-section of the portion 240 as that shown in FIG. 3B.

FIG. 4A illustrates an IC device 400A that includes a device region 404 with all portions of the IC structure 200 as shown in FIG. 3B, and further comprising a first interconnect layer 406 formed above the device region 404, and a second interconnect layer 408 formed above the first interconnect layer 406. Additional interconnect layers may be present above the second interconnect layer 408. A collection of interconnect layers such as the interconnect layers 406, 408, etc., may be referred to as a “metallization stack” 419 of the IC device 400A. Interchangeably, the metallization stack 419 may be referred to as the “back end of line (BEOL) layer(s)” of the IC device 400A, while the device region 404 may be referred to as the “front end of line (FEOL) layer(s)” of the IC device 400A.

Electrical signals, such as power and/or input/output (I/O) signals, may be routed to and/or from the devices (e.g., the transistors) of the device region 404 through one or more interconnect layers disposed on the device region 404 (illustrated in FIG. 4A as interconnect layers 406 and 408). For example, electrically conductive features of the device region 404 (e.g., the electrically conductive material 306 of the gate contact 206 and the electrically conductive via fill material 320 of the deep trench via 226) may be electrically coupled with the interconnect structures 428 of the interconnect layers 406 and 408. The interconnect structures 428 may be arranged within the interconnect layers of the metallization stack 419 to route electrical signals according to a wide variety of designs (in particular, the arrangement is not limited to the particular configuration of interconnect structures 428 depicted in FIG. 4A). Although a particular number of interconnect layers 406 and 408 is depicted in FIG. 4A, embodiments of the present disclosure include IC structures having more or fewer interconnect layers than depicted.

In some embodiments, the interconnect structures 428 may include conductive lines 428a and/or conductive vias 428b filled with an electrically conductive material such as a metal. The lines 428a may be arranged to route electrical signals in a direction of a plane that is substantially parallel with a surface of the support 102 upon which the device region 404 is formed. For example, the lines 428a may route electrical signals in a direction in and out of the page from the perspective of FIG. 4A. The vias 428b may be arranged to route electrical signals in a direction of a plane that is substantially perpendicular to the surface of the support 102 upon which the device region 404 is formed. In some embodiments, the vias 428b may electrically couple lines 428a of different interconnect layers of the metallization stack 419 together.

The interconnect layers 406 and 408 may include a dielectric material 426 disposed between the interconnect structures 428, as shown in FIG. 4A. In some embodiments, the dielectric material 426 disposed between the interconnect structures 428 in different ones of the interconnect layers 406 and 408 may have different compositions; in other embodiments, the composition of the dielectric material 426 between different interconnect layers 406 and 408 may be the same.

A first interconnect layer 406 may be formed above the device region 404. In some embodiments, the first interconnect layer 406 may include lines 428a and/or vias 428b, as shown. The lines 428a and/or the vias 428b of the first interconnect layer 406 may be coupled with contacts (e.g., gate contacts 206 and/or S/D contacts 214 of the IC structure 200) of the device region 404.

A second interconnect layer 408 may be formed above the first interconnect layer 406. In some embodiments, the second interconnect layer 408 may include vias 428b to couple the lines 428a of the second interconnect layer 408 with the lines 428a of the first interconnect layer 406. Although the lines 428a and the vias 428b are structurally delineated with a line within each interconnect layer (e.g., within the second interconnect layer 408) for the sake of clarity, the lines 428a and the vias 428b may be structurally and/or materially contiguous (e.g., simultaneously filled during a dual-damascene process) in some embodiments.

Additional interconnect layers, as desired, may be formed in succession on the second interconnect layer 408 according to similar techniques and configurations described in connection with the second interconnect layer 408 or the first interconnect layer 406. In some embodiments, the interconnect layers that are “higher up” in the metallization stack 419 in the IC device 400A (i.e., farther away from the device region 404) may be thicker. Although not specifically shown in FIG. 4A, in some embodiments, the IC device 400A may further include a solder resist material (e.g., polyimide or similar material) and one or more conductive contacts formed on the interconnect layers of the metallization stack 419.

FIG. 4B illustrates that, once the metallization stack 419 has been formed, a carrier substrate 440 may be attached to the top of the metallization stack 419 of the IC device 400A, thus providing an IC device 400B. The carrier substrate 440 may include any suitable structure that may provide adequate mechanical support for the subsequent processing steps as shown in FIGS. 4C-4F.

FIG. 4C illustrates an IC device 400C, which is substantially the same as the IC device 400B but flipped over in order to continue processing on the back side of the IC device.

FIG. 4D illustrates an IC device 400D after the start of the backside processing, where the support 102 and a portion of the device region 404 closest to the support 102 are removed (e.g., by grinding). FIG. 4D shows that, as a result, the interface material 316 at the bottom of the deep trench via 226 is removed.

FIG. 4E illustrates an IC device 400E that is substantially the same as the IC device 400D, but further includes a metallization stack 449 at the back side of the device region 404. As shown in FIG. 4E, the metallization stack 449 may include a first interconnect layer 436 formed on the back side of the device region 404, and a second interconnect layer 438 formed above the first interconnect layer 436. Additional interconnect layers may be present above the second interconnect layer 438.

Electrical signals, such as power and/or input/output (I/O) signals, may be routed to and/or from the devices (e.g., the transistors) of the device region 404 through one or more interconnect layers disposed on the back side of the device region 404 (illustrated in FIG. 4E as interconnect layers 436 and 438). For example, electrically conductive features of the device region 404 (e.g., the electrically conductive via fill material 320 of the deep trench via 226) may be electrically coupled with the interconnect structures 458 of the interconnect layers 436 and 438. The interconnect structures 458 may be arranged within the interconnect layers of the metallization stack 449 to route electrical signals according to a wide variety of designs (in particular, the arrangement is not limited to the particular configuration of interconnect structures 458 depicted in FIG. 4E). Although a particular number of interconnect layers 436 and 438 is depicted in FIG. 4E, embodiments of the present disclosure include IC structures having more or fewer interconnect layers than depicted.

In some embodiments, the interconnect structures 458 may include conductive lines 458a and/or conductive vias 458b filled with an electrically conductive material such as a metal. The interconnect layers 436 and 438 may include a dielectric material 456 disposed between the interconnect structures 458, as shown in FIG. 4E. Descriptions provided above with respect to the first interconnect layer 406, second interconnect layer 408, metallization stack 419, dielectric material 426, conductive lines 428a, and conductive vias 428b are applicable to, respectively, the first interconnect layer 436, second interconnect layer 438, metallization stack 449, dielectric material 456, conductive lines 458a, and conductive vias 458b. Therefore, in the interest of brevity, these descriptions are not repeated.

FIG. 4F illustrates an IC device 400F that is substantially the same as the IC device 400E, but after removal of the carrier substrate 440. Since the metallization stack 419 is provided on the front side of the device region 404, while the metallization stack 449 is provided on the back side, there may be features indicative of this in the IC device 400F. In particular, for certain manufacturing processes, cross-sectional shapes of interconnects in a plane such as that of FIG. 4E (e.g., in a plane substantially perpendicular to the device region 404) may be trapezoidal, i.e., a cross-section of an interconnect may have two substantially parallel sides, one of which shorter than the other. Because the interconnects 428 are formed on a front side 462 of the device region 404, their trapezoidal shapes may be arranged so that their shorter sides are closer to a back side 464 of the device region 404 than their longer sides. Similarly, because the deep trench vias 226 were formed from the same side, the trapezoidal shapes of the deep trench vias 226 may be arranged so that their shorter sides are also closer to a back side 464 of the device region 404 than their longer sides. Because the interconnects 458 are formed on the back side 464 of the device region 404, their trapezoidal shapes may be arranged so that their shorter sides are closer to a back side 464 of the device region 404 than their longer sides.

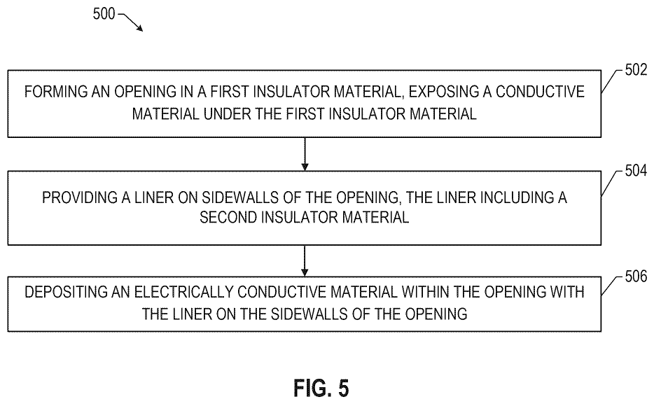

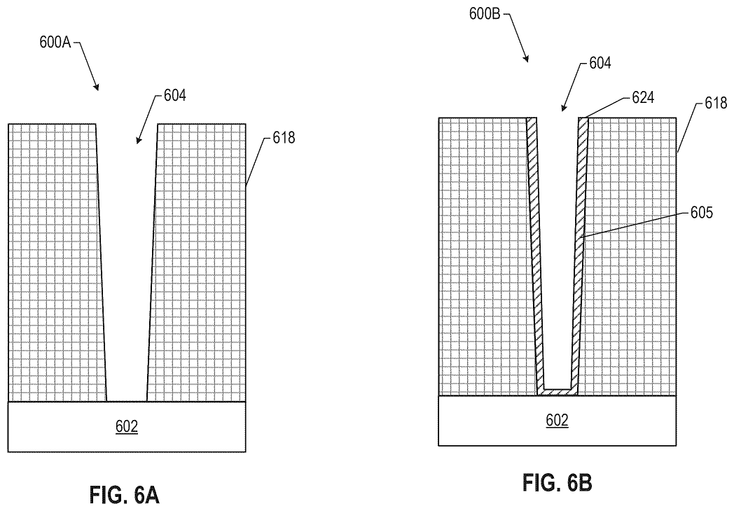

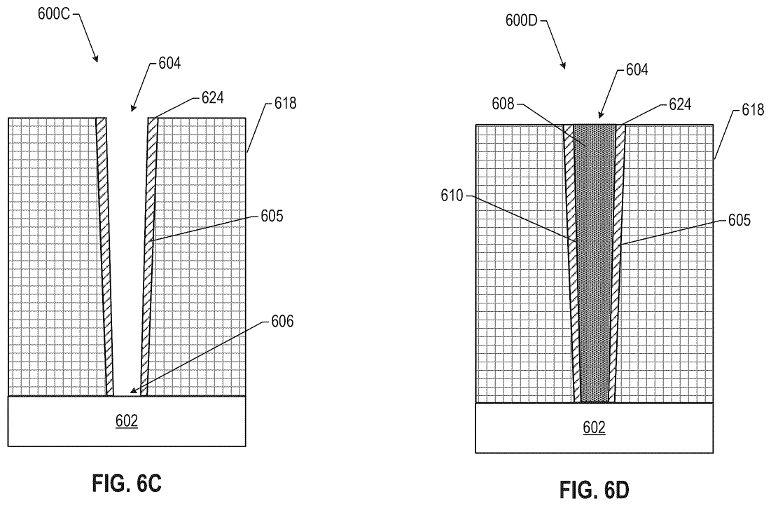

FIG. 5 is a flow diagram of an example method for fabricating an IC structure that includes a self-insulated via, in accordance with some embodiments. FIGS. 6A-6D provide cross-sectional side views at various stages in the fabrication of an example IC structure according to the method of FIG. 5, in accordance with some embodiments.

Although the operations of the method of FIG. 5 are illustrated once each and in a particular order, the operations may be performed in any suitable order and repeated as desired. For example, one or more operations may be performed in parallel to fabricate multiple IC structures with self-insulated vias substantially simultaneously. In another example, the operations may be performed in a different order to reflect the structure of an IC device in which an IC structure with a self-insulated via will be implemented.

In addition, the example fabricating method of FIG. 5 may include other operations not specifically shown in FIG. 5, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIG. 5 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 5, the method 500 begins with a process 502 of forming an opening in a first insulator material, exposing a conductive material under the first insulator material. An IC structure 600A of FIG. 6A illustrates an example result of the process 502. The IC structure 600A includes a support 602, an insulator material 618, and an opening 604 in the insulator material 618. The support 602 can be, for example, a substrate, a die, a wafer, or a chip, or any other suitable support structure such as those described above with respect to the support 102. The insulator material 618 may include any suitable insulator material, e.g., any of the ILD materials described above.

In one example, the opening 604 is a trench (e.g., via trench or deep trench). Any suitable etching technique, e.g., a dry etch, such as e.g., RF reactive ion etch (RIE) or inductively coupled plasma (ICP) RIE may be used for forming the opening 604. In some embodiments, the etch performed in the process 502 may include an anisotropic etch, using etchants in a form of e.g., chemically active ionized gas (i.e., plasma) using e.g., bromine (Br) and chloride (CI) based chemistries. In some embodiments, during the etch of the process 502, the IC structure may be heated to elevated temperatures, e.g., to temperatures between about room temperature and 200 degrees Celsius, including all values and ranges therein, to promote that byproducts of the etch are made sufficiently volatile to be removed from the surface.

The method 500 may then proceed with a process 504 of providing a liner on sidewalls of the opening, the liner including a second insulator material. IC structures 600B of FIGS. 6B and 600C of FIG. 6C illustrate example results of the process 504. Turning first to FIG. 6B, the IC structure 600B includes a liner 624 on the sidewalls of the opening 604. In the example illustrated in FIG. 6B, the liner 624 is also present on a bottom of the opening 604. The liner 624 can have the same or a different material composition than the insulator material 618, and the same or a different density than the insulator material 618. In one example, the liner 624 includes an insulator material that has at least one material property that is different than the corresponding material property of the insulator material 618, where material properties include one or more of: material composition, density, and dielectric constant. In one such example, the insulator material 618 is one insulator material (e.g., silicon nitride or another insulator material) and the insulator material 605 is a different insulator material (e.g., silicon oxide or another insulator material). In other examples, both the insulator material 618 and the insulator material 605 are the same insulator material, such as silicon nitride, silicon oxide, silicon carbide, a composite including silicon and one or more of oxygen, nitrogen, and carbon, or another suitable insulator material. The liner 624 can be deposited in the process 504 using a technique such as atomic layer deposition (ALD), chemical vapor deposition (CVD), plasma enhanced CVD (PECVD), or/and physical vapor deposition (PVD) processes such as sputter.

In an example in which the insulator material 605 is deposited on both the sidewalls and the bottom of the opening 604, the insulator material 605 at the bottom of the opening 604 is removed to enable the resulting via to electrically connect with a conductive element coupled with the via. The IC structure 600C of FIG. 6C illustrates an example of the IC structure 600B after removing the insulator material 605 from the bottom 606 of the opening 604. Thus, the IC structure 600C includes the liner 624 on sidewalls of the opening 604, but not on the bottom 606 of the opening 604. Any suitable etching technique, e.g., a dry etch, such as e.g., RF RIE or inductively coupled plasma (ICP) RIE may be used for removing the insulator material 605 from the bottom 606 of the opening 604.

The method 500 may then proceed with a process 506 of depositing an electrically conductive material within the opening with the liner on the sidewalls of the opening. An IC structure 600D of FIG. 6D illustrates an example result of the process 506. The IC structure 600D shows the lined opening 604 filled with a conductive material 608 to form a conductive via 610. In the example in FIG. 6D, the liner 624 is in contact with both the conductive material 608 and the insulator material 618 surrounding the conductive via 610. The electrically conductive material may include any suitable electrically conductive material, such as any of those described above, and may be deposited in the process 506 using a technique such as ALD, CVD, plasma enhanced CVD (PECVD), or/and PVD processes such as sputter.

The IC structure 600D can then undergo additional processing, for example, to remove the support 602 and form metallization layers over one or both sides of the IC structure 600D to electrically connect the conductive via 610 to other conductive elements and/or devices, such as shown in FIGS. 3A-3C and FIGS. 4A-4F.

Performing the method 500 may result in features in the final IC structures that are characteristic of the use of the method 500. For example, one such feature is illustrated in the IC structure 600D shown in FIG. 6D, which shows a liner 624 that includes an insulator material on sidewalls of the via opening 604. Similarly, the IC structures shown in FIGS. 3B, 3C, and FIGS. 4A-4F illustrate a liner 324 on sidewalls of the deep trench 226.

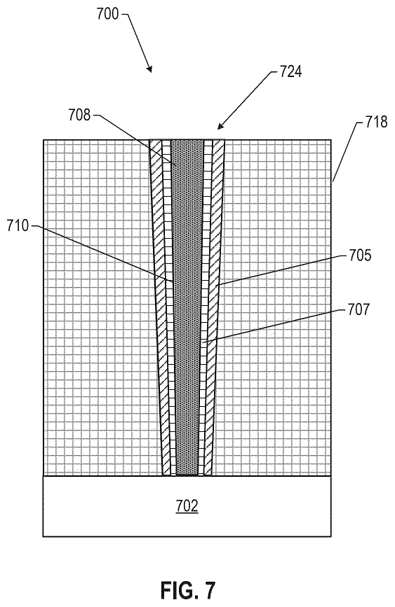

FIG. 7 illustrates another example of an IC structure 700 with a self-insulated via 710 with a multi-layered insulative liner, in accordance with embodiments. In the example illustrated in FIG. 7, the IC structure 700 includes a via 710 with a conductive material 708 and an insulator material 718 surrounding the via 710. The insulator material 718 may include any suitable insulator material, e.g., any of the ILD materials described above. The IC structure 700 also includes a multi-layered insulative liner 724 between the insulator material 718 and the conductive material 708 of the via 710. In the illustrated example, the liner 724 includes an insulator material 705 and an insulator material 707, where the insulator material 705 has a different material composition than the insulator material 707. In the illustrated example, the insulator material 707 is between the conductive material 708 and the insulator material 705, and the insulator material 705 is between the insulator material 707 an the insulator material 718. In one example, one of the insulator materials 705, 707 have the same material composition as the insulator material 718. Although two layers of insulator material are shown, in other examples, an insulative liner may include more than two layers of insulator material.

The thickness of the insulator material 705 and the thickness of the insulator material 707 may be the same or different. In one example, the combined thickness (e.g., the thickness of the liner 724) is about less than 50% of the width of the conductive material 708, where a thickness of the liner 724 and the width of the conductive material 708 are dimensions measured in a plane substantially parallel to the support 702.

A method for fabricating an IC structure 700 with a self-insulated via with a liner having multiple insulator materials can involve similar processes as in the method 500 FIG. 5, but with some additional processes (e.g., additional deposition and etching processes) to form the additional layer(s) of insulator material on sidewalls of the via opening. Providing a liner with multiple insulator materials may have the additional benefit of enabling the properties (e.g., electrical properties such as capacitance) of the self-insulated via to be tuned to improve performance.

Thus, IC structures including electrically self-insulated vias as described herein can prevent unintentional electrical connection between vias and adjacent devices. Additionally, IC structures including vias with an insulative liner on sidewalls of the via can enable fabrication processes in which a wider via opening is formed than would conventionally be possible. In one such example, the width of the resulting via can be controlled by controlling the thickness of the insulator material on the sidewalls of the via.

IC devices/structures that include self-insulated vias as described herein (e.g., as described with reference to FIGS. 3-7) may be used to implement any suitable components. For example, in various embodiments, IC structures described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

The IC devices and structures disclosed herein, e.g., the IC devices 100, 200, or 400, IC structures 600A, 600B, 600D, 600D, or 700, or any variations thereof, may be included in any suitable electronic component.

FIGS. 8-11 illustrate various examples of apparatuses that may include any of the IC devices disclosed herein.

FIG. 8 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures as described herein (e.g., any of the IC devices 100, 200, 400 or IC structures 600A, 600B, 600D, or 700, described herein), one or more transistors (e.g., nanoribbon transistors of the IC devices 100, 200, 400) and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 8) or other logic that is configured to store information in the memory devices or execute instructions stored in the memory array.

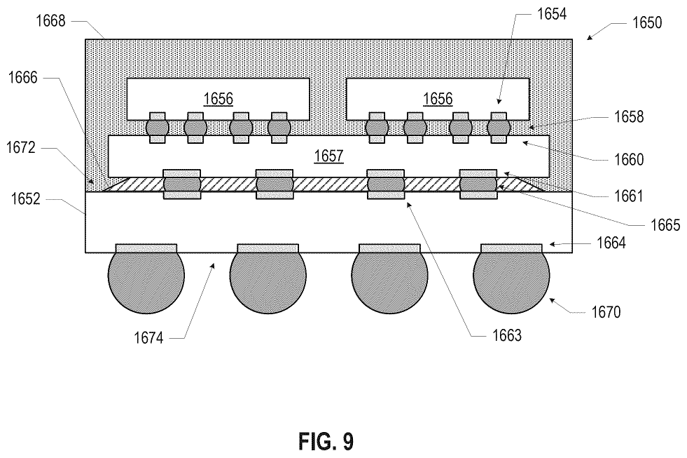

FIG. 9 is a side, cross-sectional view of an example IC package 1650 that may include one or more IC structures in accordance with any of the embodiments disclosed herein (e.g., any of the IC devices 100, 200, or 400, or IC structures 600A, 600B, 600D, 600D, or 700, described herein). In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnects 428 discussed above with reference to FIG. 4, 6, or 7.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 6 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 6 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

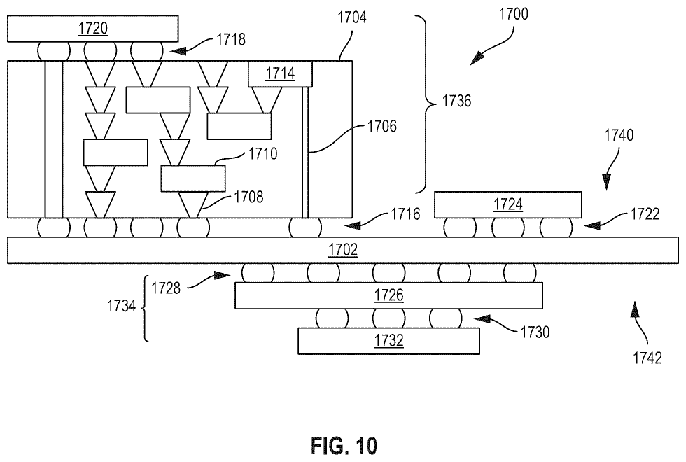

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 9 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 10.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 9 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 9, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 10 is a side, cross-sectional view of an IC device assembly 1700 that may include one or more IC packages or other electronic components (e.g., a die) including one or more IC devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 8 (e.g., may include one or more the IC devices 100, 200, or 400, IC structures 600A, 600B, 600D, 600D, or 700).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 10 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 10), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 10, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 8), an IC device (e.g., any of the IC devices 100, 200, 400, described herein, or any combination of such IC devices), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 10, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 10 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

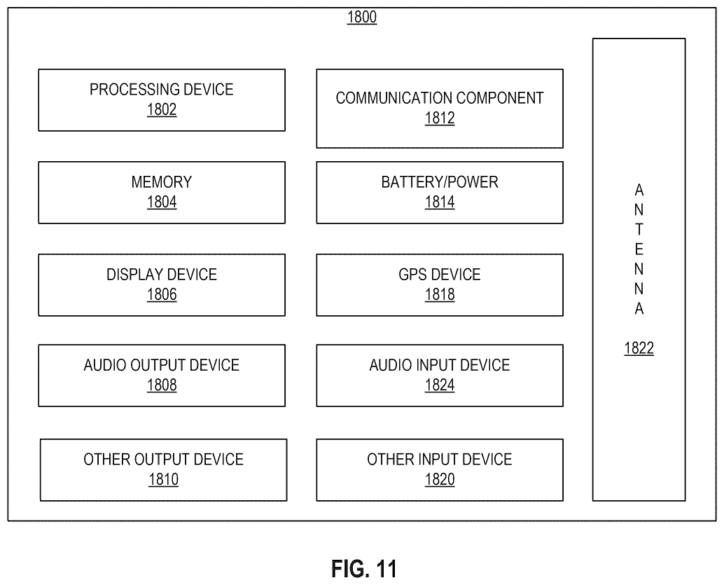

FIG. 11 is a block diagram of an example electrical device 1800 that may include one or more IC structures 100 in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 11 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 11, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure that includes a first layer including a first conductive element (e.g., a conductive via, contact, or other conductive element), a second layer over the first layer, the second layer including a second conductive element, and a third layer between the first layer and the second layer. The third layer includes a conductive via (e.g., a self-insulated conductive via) between the first conductive element and the second conductive element, and a first insulator material (e.g., an ILD or other suitable insulator material) surrounding the conductive via. The conductive via includes a conductive material and an insulator layer (e.g., a liner including one or more layers of insulator material) between the conductive material and the first insulator material.

In one example, the insulator layer includes a second insulator material, wherein at least one material property of the second insulator material is different than a corresponding material property of the first insulator material.

Example 2 provides an IC structure according to example 1, where the at least one material property includes one or more of: density, material composition, and dielectric constant.

Example 3 provides an IC structure according to examples 1 or 2, where the conductive material is in contact with the insulator layer.

Example 4 provides an IC structure according to any one of examples 1-3, where the insulator layer is in contact with the first insulator material.

Example 5 provides an IC structure according to any one of examples 1-4, where the second insulator material has a different density (e.g., higher density or lower density) than the first insulator material.

Example 6 provides an IC structure according to any one of examples 1-5, where the second insulator material has a different material composition than the first insulator material.

Example 7 provides an IC structure according to any one of examples 1-5, where the second insulator material has the same material composition as the first insulator material.

Example 8 provides an IC structure according to any one of examples 1-7, where the insulator layer further includes a third insulator material (e.g., the insulator layer is or includes a multi-layered liner), where the second insulator material is between the first insulator material and the third insulator material and the third insulator material is between the second insulator material and the conductive material, and where a material composition of the second insulator material is different from a material composition of the third insulator material.

Example 9 provides an IC structure according to example 8, where one of the second insulator material and the third insulator material has the same material composition as the first insulator material.

Example 10 provides an IC structure according to any one of examples 1-9, where a thickness of the insulator layer is less than about 50% of a width of the conductive material.

Example 11 provides an IC structure according to any one of examples 1-10, where a thickness of the insulator layer is greater than about 3 nanometers.

Example 12 provides an IC structure including a first layer including a first conductive element, a second layer over the first layer, where the second layer includes a second conductive element, and a third layer between the first layer and the second layer. The third layer includes a conductive interconnect (e.g., a self-insulated conductive via) between the first conductive element and the second conductive element and a first insulator material surrounding the conductive interconnect. The conductive interconnect includes a conductive fill material and a liner between the conductive fill material and the first insulator material. The liner includes a second insulator material, where the second insulator material has a different density than the first insulator material.

Example 13 provides an IC structure according to example 12, where the conductive fill material is in contact with the liner.

Example 14 provides an IC structure according to examples 12 or 13, where the liner is in contact with the first insulator material.

Example 15 provides an IC structure according to any one of examples 12-14, where the second insulator material has a higher density than the first insulator material.

Example 16 provides an IC structure according to any one of examples 1-15, where the IC structure includes or is a part of a central processing unit.

Example 17 provides an IC structure according to any one of examples 1-16, where the IC structure includes or is a part of a memory device.

Example 18 provides an IC structure according to any one of examples 1-17, where the IC structure includes or is a part of a logic circuit.

Example 19 provides an IC structure according to any one of examples 1-18, where the IC structure includes or is a part of input/output circuitry.

Example 20 provides an IC structure according to any one of examples 1-19, where the IC structure includes or is a part of a field programmable gate array transceiver.

Example 21 provides an IC structure according to any one of examples 1-20, where the IC structure includes or is a part of a field programmable gate array logic.

Example 22 provides an IC structure according to any one of examples 1-21, where the IC structure includes or is a part of a power delivery circuitry.

Example 23 provides an IC package including an IC component including a first conductive contact, where the IC component is one of a package substrate, a carrier substrate, an interposer, or a further IC die and an IC die coupled to the IC component. The IC die includes a first layer including a first conductive element coupled to the first conductive contact, a second layer over the first layer, the second layer including a second conductive element, and a conductive via between the first conductive element and the second conductive element, where the conductive via is surrounded by a first insulator material. The conductive via includes a conductive fill material and a liner between the conductive fill material and the first insulator material, wherein the liner includes a second insulator material, and wherein the second insulator material has a higher density than the first insulator material.

Example 24 provides an IC package of example 23, where the conductive fill material is in contact with the liner.

Example 25 provides an IC package of examples 23 or 24, where the liner is in contact with the first insulator material.

Example 26 provides an IC package according to any one of examples 23-25, where the second insulator material has a different material composition than the first insulator material.

Example 27 provides an IC package according to any one of examples 23-25, where the second insulator material has the same material composition as the first insulator material.

Example 28 provides an IC package that includes an IC die including an IC structure according to any one of examples 1-22, and a further IC component, coupled to the IC die.

Example 29 provides an IC package according to example 28, where the further IC component includes a package substrate.

Example 30 provides an IC package according to example 28, where the further IC component includes an interposer.

Example 31 provides an IC package according to example 28, where the further IC component includes a further IC die.

Example 32 provides a computing device that includes a carrier substrate and an IC structure coupled to the carrier substrate, where the IC structure is an IC structure according to any one of examples 1-22, or the IC structure is included in the IC package according to any one of examples 23-31.

Example 33 provides a computing device according to example 32, where the computing device is a wearable or handheld computing device.

Example 34 provides a computing device according to examples 32 or 33, where the computing device further includes one or more communication chips.

Example 35 provides a computing device according to any one of examples 32-34, where the computing device further includes an antenna.

Example 36 provides a computing device according to any one of examples 32-35, where the carrier substrate is a motherboard.

Example 37 provides a method of fabricating an IC structure, where the method includes forming an opening (e.g., a trench or via trench) in a first insulator material, exposing a conductive material under the first insulator material, providing a liner on sidewalls of the opening, the liner including a second insulator material, and depositing an electrically conductive material within the opening with the liner on the sidewalls of the opening.

Example 38 provides a method according to example 37, where the second insulator material includes a different material than the first insulator material (e.g., a different material composition).

Example 39 provides a method according to example 37, where the second insulator material includes a same material as the first insulator material (e.g., the same material composition).

Example 40 provides a method according to any one of examples 37-39, where the second insulator material has a higher density than the first insulator material.

Example 41 provides a method according to any one of examples 37-40, where forming the liner includes depositing the second insulator material on the sidewalls and on the conductive material and removing the second insulator material from the conductive material.

Example 42 provides a method of anyone of examples 37-41, where forming the liner includes providing a first insulator layer on the sidewalls of the opening and providing a second insulator layer on the first insulator layer, where the second insulator layer includes a different material than the first insulator layer.

Example 43 provides a method according to any one of examples 37-42, where the IC structure is an IC structure according to any one of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a first layer including a first conductive element;
a second layer over the first layer, the second layer including a second conductive element; and
a third layer between the first layer and the second layer, the third layer including:
a conductive via between the first conductive element and the second conductive element, and
a first insulator material surrounding the conductive via,
wherein the conductive via includes:
a conductive material, and
an insulator layer between the conductive material and the first insulator material, the insulator layer including a second insulator material, wherein at least one material property of the second insulator material is different than a corresponding material property of the first insulator material.

2. The IC structure of claim 1, wherein:
the at least one material property includes one or more of: density, material composition, and dielectric constant.

3. The IC structure of claim 1, wherein:
the conductive material is in contact with the insulator layer.

4. The IC structure of claim 3, wherein:
the insulator layer is in contact with the first insulator material.

5. The IC structure of claim 1, wherein:
the second insulator material has a higher density than the first insulator material.

6. The IC structure of claim 1, wherein:
the second insulator material has a different material composition than the first insulator material.

7. The IC structure of claim 1, wherein:
the second insulator material has a same material composition as the first insulator material.

8. The IC structure of claim 1, wherein:
the insulator layer further includes a third insulator material,
the second insulator material is between the first insulator material and the third insulator material,
the third insulator material is between the second insulator material and the conductive material, and
a material composition of the second insulator material is different from a material composition of the third insulator material.

9. The IC structure of claim 8, wherein:
one of the second insulator material and the third insulator material has a same material composition as the first insulator material.

10. The IC structure of claim 1, wherein:
a thickness of the insulator layer is less than about 50% of a width of the conductive material.

11. The IC structure of claim 10, wherein:
the thickness of the insulator layer is greater than about 3 nanometers.

12. An integrated circuit (IC) structure, comprising:
a first layer including a first conductive element;
a second layer over the first layer, the second layer including a second conductive element; and
a third layer between the first layer and the second layer, the third layer including:
a conductive interconnect between the first conductive element and the second conductive element, and
a first insulator material surrounding the conductive interconnect,
wherein the conductive interconnect includes:
a conductive fill material, and
a liner between the conductive fill material and the first insulator material, wherein the liner includes a second insulator material, and wherein the second insulator material has a different density than the first insulator material.

13. The IC structure of claim 12, wherein:
the conductive fill material is in contact with the liner.

14. The IC structure of claim 13, wherein:
the liner is in contact with the first insulator material.

15. The IC structure of claim 12, wherein:
the second insulator material has a higher density than the first insulator material.

16. An integrated circuit (IC) package comprising:
an IC component including a first conductive contact, wherein the IC component is one of a package substrate, a carrier substrate, an interposer, or a further IC die; and
an IC die coupled to the IC component, the IC die including:
a first layer including a first conductive element coupled to the first conductive contact,
a second layer over the first layer, the second layer including a second conductive element, and
a conductive via between the first conductive element and the second conductive element, wherein the conductive via is surrounded by a first insulator material,
wherein the conductive via includes a conductive fill material and a liner between the conductive fill material and the first insulator material, wherein the liner includes a second insulator material, and wherein the second insulator material has a higher density than the first insulator material.

17. The IC package of claim 16, wherein:
the conductive fill material is in contact with the liner.

18. The IC package of claim 17, wherein:
the liner is in contact with the first insulator material.

19. The IC package of claim 16, wherein:
the second insulator material has a different material composition than the first insulator material.

20. The IC package of claim 16, wherein:
the second insulator material has a same material composition as the first insulator material.
